(19) United States
(12) Patent Application Publication
(10) Pub. No.: US 2005/0081910 A1
(43) Pub. Date: Apr. 21, 2005

(54) High efficiency tandem solar cells on silicon substrates using ultra thin germanium buffer layers

(76) Inventors: David T. Danielson, Somerville, MA (US); Jeremy Graham, Norman, OK (US); Kazumi Wada, Lexington, MA (US); Trisha M. Montalbo, Cambridge, MA (US); Lionel C. Kimerling, Concord, MA (US)

Correspondence Address: Gauthier & Connors LLP, Suite 3300, 225 Franklin Street, Boston, MA, 02110, US

(21) Appl. No.: 10/922,420

(22) Filed: Aug. 20, 2004

Related U.S. Application Data
(60) Provisional application No. 60/497,167, filed on Aug. 22, 2003.

(51) Int. Cl. H01L 31/00

(52) U.S. Cl. 136/255; 136/249

(57) ABSTRACT

A system is disclosed for providing electrical power responsive to solar energy. The system includes a Si cell, an AlGaAs cell, and a Ge cell. The Si cell is for providing electrical power responsive to solar energy within a first frequency range. The AlGaAs cell is coupled to a first side of the Si cell, and is for providing electrical power responsive to solar energy within a second frequency range. The Ge cell is coupled to a second side of the Si cell, and the Ge cell provides electrical power responsive to solar energy within a third frequency range.

### PRIORITY

The present application claims priority to U.S. Provisional Patent Application Ser. No. 60/497,167 filed Aug. 22, 2003.

### BACKGROUND

The invention relates to the field of solar cells, and in particular to tandem solar cells.

Photovoltaic cells, commonly known as solar cells, are devices that convert light energy into electric energy. Solar cells provide a number of distinct advantages when compared to conventional energy sources. For example, solar cells produce electricity without any harmful emissions and do not rely on finite fossil fuel supplies. Furthermore, solar cells create electric power without any active supply of fuel and thus can serve as sources of electric power in remote terrestrial locations as well as in space.

Currently, the most widely deployed solar cell devices consist of a single solar cell made of silicon (Si). These Si solar cells have been perfected to a level that they have very nearly reached their theoretical efficiency limit of ˜26% in conversion of solar energy to electricity. Silicon solar cells produce electricity more cost-effectively than any other type of solar cell. Even so, however, the current cheapest Si solar cells prices of ˜$3/peak watt of electric power generation still result in electricity prices of 25-40 cents/kWh, at least 5 times the current electricity price from conventional energy sources such as coal and natural gas. Thus, the quest to develop new solar cell devices with higher efficiency and lower cost than that achieved with single silicon solar cells continues in industry and academia with great interest.

One of the most promising technologies for realizing solar cells with higher efficiency and lower cost relative to silicon solar cells is that of tandem solar cells. For example, U.S. Pat. Nos. 6,340,788 and 5,009,719 as well as U.S. Published Patent Applications Nos. 2004/0079408 and 2002/0179142 disclose tandem solar cells. In a tandem solar cell, multiple solar cells consisting of different materials are stacked upon each other. In order for electricity to be produced from light, a solar cell must be able to perform two primary functions: 1) it must be able to absorb the incident sunlight to produce free electronic carriers and 2) it must be able to collect these carriers to produce electric power. The ability of a solar cell to absorb sunlight is determined by an intrinsic materials property called the bandgap energy. A material with a given bandgap energy has the ability to absorb sunlight of energy equal to or greater than its bandgap. Most of sunlight energy falls in the energy range from 0.50 eV-4.13 eV and the solar spectrum peaks at approximately 2.5 eV. As a note, the wavelength, λ, and energy, E, of light can be interconverted using λ(μm)=1.239/E(eV). Accordingly, light energies and bandgap energies can be converted to light wavelengths and bandgap wavelengths. The only difference in this case is that a material having a given bandgap wavelength can only absorb light wavelengths smaller than its bandgap wavelength. A further important consideration in tandem solar cells is that a solar cell consisting of a material with a given bandgap energy converts light energy most efficiently in a narrow range of energies just above its bandgap energy.

According to all these considerations, in order to absorb sunlight as efficiently as possible a tandem solar cell must consist of a stack of multiple photovoltaic cells consisting of a highest bandgap material on the side upon which light is incident, with many successive layers beneath it having progressively lower bandgaps. Such a structure results in two advantages: 1) a larger portion of the sunlight spectrum is absorbed and 2) more of the sunlight absorbed is absorbed at energies close to the bandgap energies of the cells of which the tandem cell consists, resulting in higher efficiencies within each individual cell, and thus higher efficiency for the tandem cell.

An additional key consideration in the design of tandem solar cells is that the net tandem solar cell device current is dictated by the lowest current present in any of the Individual sub-cells within the tandem solar cell. Accordingly, current-matching between all sub-cells is ideal and puts a further constraint on the bandgaps that the materials of the sub-cells must have in order for a tandem cell to exhibit high efficiency. Effectively, the materials must be selected to apportion the absorption and collection of free charge carriers from sunlight evenly, which requires the sub-cells to have very specific sets of bandgap energy values for optimum efficiency. The maximum efficiency of a current-matched tandem solar cell generally increases with the number of sub-cells, and accordingly a larger number of current-matched sub-cells is preferable to a smaller number with regard to maximizing tandem solar cell device efficiency.

As mentioned previously, however, solar cells must not only absorb sunlight, but also must collect the light-generated free electronic carriers that are generated, in order to produce electric power. In order for a solar cell to efficiently collect these carriers, the solar cell materials must be of as high crystalline perfection as possible. Traditionally, in order to easily grow high crystalline quality solar cell materials on top of one another, as required in a tandem solar cell, all the different solar cell materials within one tandem cell have had to have identical crystalline structures with the same lattice constant in order for high-quality tandem cells with high efficiency to be produced. Materials systems with this property are called lattice-matched. When a material is grown upon another material with a different crystalline structure or lattice constant, crystalline defects such as misfit and threading dislocations that degrade the crystalline structure and free electronic carrier collection are formed in the grown material. Accordingly, lattice-mismatched materials systems typically have low solar cell efficiency performance. The highest efficiency tandem solar cells fabricated to date, demonstrating efficiencies of ˜30%, consist of lattice-matched GaInP₂/GaAs/Ge structures based upon expensive Ge substrate materials technology. Accordingly, these tandem cells have prohibitive costs for typical solar cell application and will not exceed the cost performance of single silicon solar cells.

A solution to the current solar cell cost problem would be to merge the high-efficiency of tandem solar cells with the low-cost of silicon substrate-based solar cells. An ideal embodiment would include a high-efficiency tandem solar cell consisting of as many current-matched, high crystalline quality sub-cells as possible integrated onto an inexpensive silicon substrate which is used as a growth substrate and an active tandem cell sub-cell. A critical problem, however, is that there exist no common materials that are lattice-matched to silicon that can provide the bandgap values required for the necessary absorption over the whole solar spectrum, along with tandem cell sub-cell current matching. Accordingly, attempts to date to make tandem solar cells on silicon substrates have resulted in high threading dislocation density (˜10⁹ dislocation/cm²) and poor crystalline quality; and thus accordingly have poor solar energy conversion efficiency.

Attempts to date have focused on two distinct strategies: 1) growth of lattice mismatched layers directly on Si with or without low quality, thick buffers and 2) graded, buffer technologies in order to alleviate the lattice-mismatch problem and grow pseudo-lattice matched layers on Si. The former method has been attempted and has resulted in low quality (˜10⁹ dislocations/cm²), low efficiency cells. The latter method has involved growing relatively high quality (˜10⁶ dislocations/cm²) GaInP₂/GaAs/Ge three sub-cell tandem solar cells on silicon substrates using thick (˜10 μm) layers of SiGe, grading from pure Si at the silicon substrate, through a number of layers of SiGe of increasing Ge concentration up to pure Ge, and by then growing GaAs and GaInP₂ lattice-matched to the Ge layer. This method however, has the disadvantage that due to the thick SiGe buffer, it is not possible to integrate the buffer or any layers beneath it into the active tandem cell structure.

There remains a need, therefore, for solar cells that are economical to produce and provide more efficient conversion of light into electrical energy.

### SUMMARY

A system is disclosed for providing electrical power responsive to solar energy. In accordance with an embodiment, the system includes a Si cell, an AlGaAs cell, and a Ge cell. The Si cell is for providing electrical power responsive to solar energy within a first frequency range. The AlGaAs cell is coupled to a first side of the Si cell, and is for providing electrical power responsive to solar energy within a second frequency range. The Ge cell is coupled to a second side of the Si cell, and the Ge cell provides electrical power responsive to solar energy within a third frequency range.

In accordance with another embodiment, the system includes a Si cell, a first AlGaAs cell, a second AlGaAs cell, and a Ge cell. The Si cell is for providing electrical power responsive to solar energy within a first frequency range. The first AlGaAs cell is coupled to a first side of the Si cell, and is for providing electrical power responsive to solar energy within a second frequency range. The second AlGaAs cell is coupled to the first AlGaAs cell, and is for providing electrical power responsive to solar energy within a third frequency range. The Ge cell is coupled to a second side of the Si cell, and is for providing electrical power responsive to solar energy within a fourth frequency range.

In accordance with another embodiment the system includes a Si cell, an AlGaAs cell and a Ge buffer layer. The Si cell is for providing electrical power responsive to solar energy within a first frequency range. The AlGaAs cell is coupled to a first side of the Si cell, and is for providing electrical power responsive to solar energy within a second frequency range. The Ge buffer layer is less than about 60 nm in thickness and is positioned between the Si cell and the AlGaAs cell.

In accordance with yet another embodiment, the system includes a Si cell, first and second AlGaAs cells and a first SiGe cell. The Si cell is for providing electrical power responsive to solar energy within a first frequency range. The first AlGaAs cell is coupled to a first side of the Si cell, and is for providing electrical power responsive to a solar energy within a second frequency range. The second AlGaAs cell is coupled to the first AlGaAs cell, and is for providing electrical power responsive to a solar energy within a third frequency range. The first SiGe cell is coupled to a second side of the Si cell, and is for providing electrical power responsive to a solar energy within a fourth frequency range.

### BRIEF DESCRIPTION OF THE ILLUSTRATED EMBODIMENTS

The following detailed description may be further understood with reference to the accompanying drawings in which:

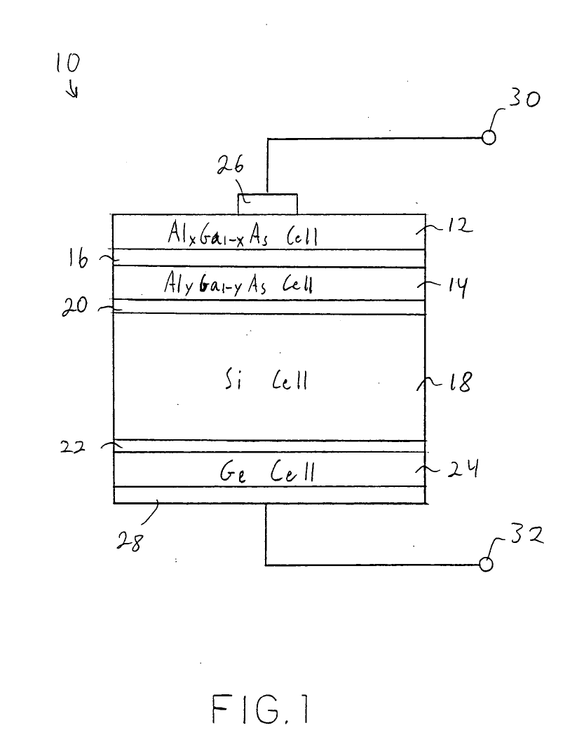

FIG. 1 shows an illustrative diagrammatic side view of a photovoltaic device in accordance with an embodiment of the invention;

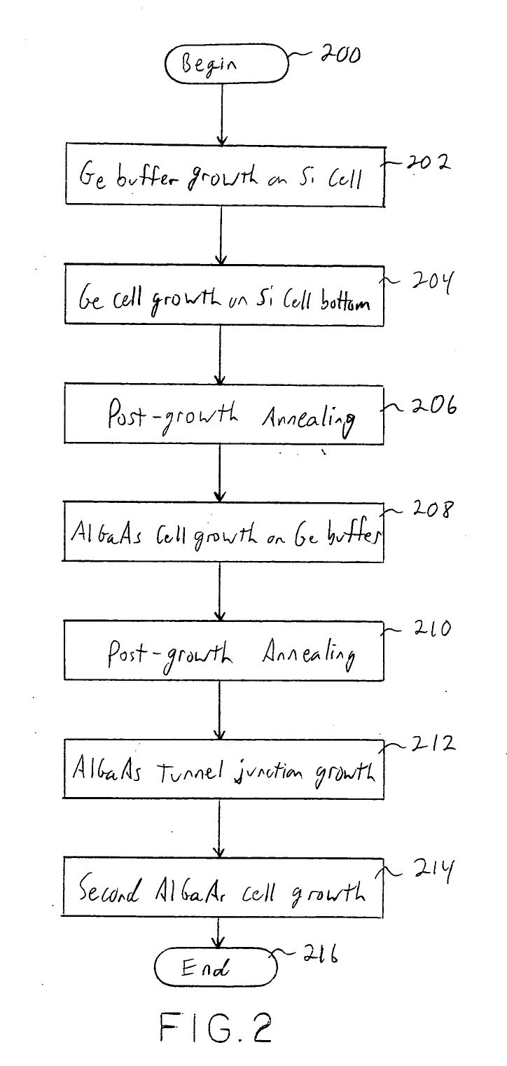

FIG. 2 shows an illustrative diagrammatic flowchart of a method of forming the device shown in FIG. 1;

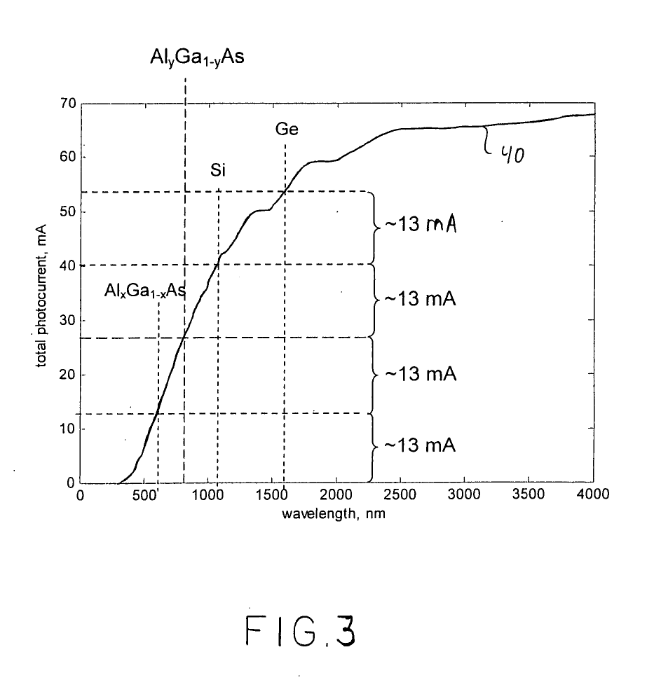

FIG. 3 shows an illustrative graphical view of total collected photocurrent under the AM1.5 solar spectrum versus wavelength for a device as shown in FIG. 1;

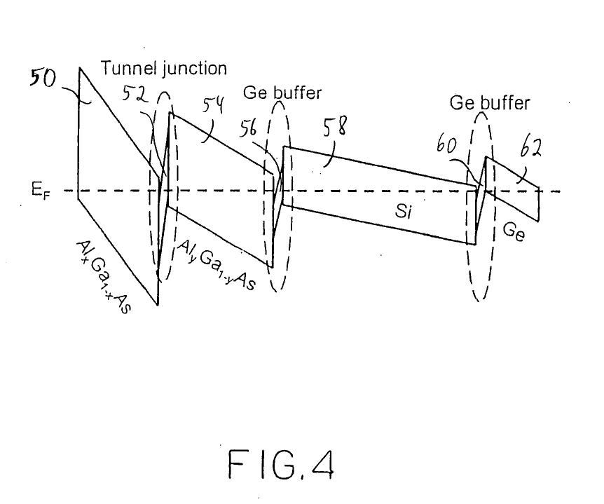

FIG. 4 shows an illustrative diagrammatic view of an energy diagram for a device as shown in FIG. 1; and

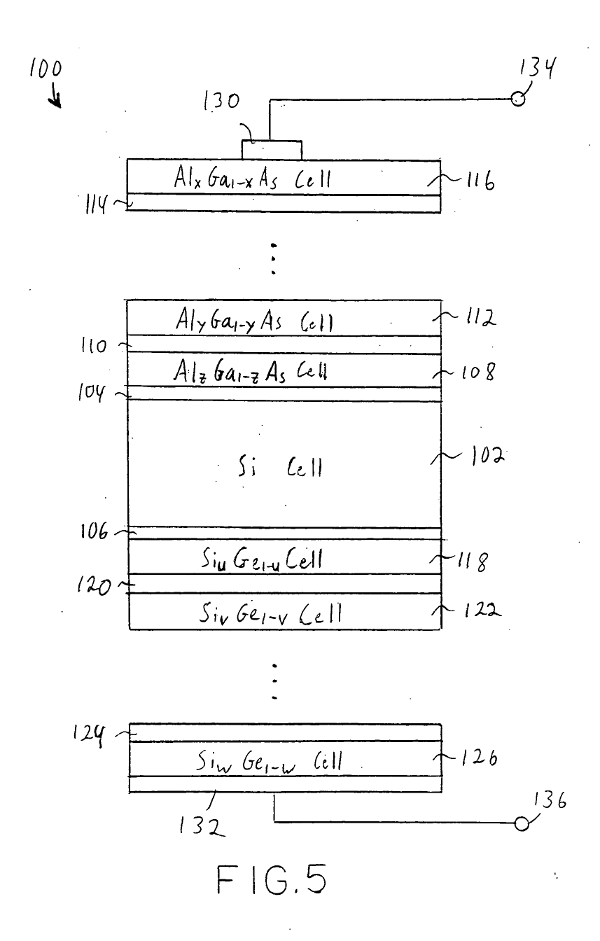

FIG. 5 shows an illustrative diagrammatic side view of a photovoltaic device in accordance with another embodiment of the invention.

The drawings are shown for illustrative purposes only and are not to scale.

### DETAILED DESCRIPTION OF THE ILLUSTRATED EMBODIMENTS

Applicants have discovered that tandem cell structures based upon silicon substrates may be formed in accordance with various embodiments of the invention. The materials Ge, AlAs, GaAs, AlₓGa₁₋ₓAs (consisting of all compositions intermediate between AlAs (2.67 eV(direct)) and GaAs (1.42 eV)), and GaInP₂ are all lattice-matched and offer a wide variety of bandgap values. For example, a four sub-cell tandem cell based upon Ge on the backside and two AlGaAs top cells of different compositions on the front-side may be optimized if a material having a bandgap of ˜1.0 eV is placed between the Ge and the AlGaAs layers. Fortuitously, silicon's bandgap of 1.12 eV is very well suited for this layer. Furthermore, the use of a high-quality ultra-thin Ge growth buffer on each side of a silicon wafer allows for the high-quality growth of both Ge and all compositions of AlGaAs on Si. The added fact that such a thin Ge buffer is sufficient for high-quality Ge and AlGaAs growth on Si greatly minimizes the parasitic absorption that inevitably occurs in low bandgap growth buffers and makes this cell structure highly promising for a highly-efficient, low-cost tandem solar cell technology.

Such high quality germanium layers may be grown directly on silicon by use of an ultra high vacuum chemical vapor deposition (UHV-CVD) low temperature germanium buffer layer deposition followed by thermal cyclic annealing. The formation of such high quality germanium layers with low threading dislocation densities of ˜10⁷ cm⁻² using germanium buffer layers of ˜50 nm have been demonstrated in U.S. Pat. No. 6,625,110. An object of this invention is to provide high-efficiency tandem solar cells on low-cost silicon substrates. This is achieved, in part, through the use of ultra-thin high-quality Ge growth buffer layers grown by ultra high vacuum chemical vapor deposition.

A system is disclosed for providing electrical power responsive to solar energy within a wide range of energies. In accordance with an embodiment, the system includes a Si substrate-based cell, a grown AlGaAs cell, and a grown Ge cell. The grown AlGaAs cell is coupled to a first side of the Si cell, the side upon which light is incident, and is for providing electrical power responsive to high energy solar energy. The Si substrate-based cell is for providing electrical power responsive to solar energy at intermediate energies. The grown Ge cell is coupled to a second side of the Si cell, and the Ge cell provides electrical power responsive to solar energy at low energies. The exact composition of the AlGaAs sub-cell material is of such a composition as to provide current matching with the Si and Ge sub-cells and is dependent upon the exact thickness of each sub-cell.

In accordance with another embodiment, the system includes a Si cell, a first Al_{y}Ga_{1-y}As cell, a second AlₓGa₁₋ₓAs cell, and a Ge cell. The bandgap of the second AlₓGa₁₋ₓAs cell is larger than that of the first Al_{y}Ga_{1-y}As cell in this embodiment, requiring that 1>x>y>0. The first Al_{y}Ga_{1-y}As cell is coupled to a first side of the Si cell, the side upon which light is made incident. The second AlₓGa_{1-y}As cell is coupled on the side of the first Al_{y}Ga_{1-y}As opposite the Si substrate. The Ge cell is coupled to the second side of the Si substrate-based cell. The second AlₓGa₁₋ₓAs cell is for providing electric power responsive to solar energy of high energy. The first Al_{y}Ga_{1-y}As cell is for providing electric power responsive to solar energy of slightly lower energy. The Si substrate-based cell is for providing electric power responsive to solar energy of even lower energy. The Ge cell is for providing electric power responsive to solar energy of the lowest energy.

In accordance with another embodiment the system includes a Si cell, an AlGaAs cell and a Ge buffer layer. The Si cell is for providing electrical power responsive to solar energy within a first frequency range. The AlGaAs cell is coupled to a first side of the Si cell, and is for providing electrical power responsive to solar energy within a second frequency range. The Ge buffer layer is less than about 60 nm in thickness and is positioned between the Si cell and the AlGaAs cell.

In accordance with yet another embodiment, the system includes a Si cell, first and second AlGaAs cells and a first SiGe cell. The Si cell is for providing electrical power responsive to solar energy within a first frequency range. The first Al_{y}Ga_{1-y}As cell is coupled to a first side of the Si cell, and is for providing electrical power responsive to solar energy within a second frequency range. The second AlₓGa₁₋ₓAs cell is coupled to the first Al_{y}Ga_{1-y}As cell, and is for providing electrical power responsive to solar energy within a third frequency range. The first SiGe cell is coupled to a second side of the Si cell, and is for providing electrical power responsive to solar energy within a fourth frequency range. In further embodiments, a high bandgap AlGaAs layer may be provided on the top surface of the device for surface passivation to make the surface electrically inactive.

As shown in FIG. 1, a photovoltaic device 10 in accordance with an embodiment of the invention includes a first cell 12 formed of AlₓGa₁₋ₓAs, and a second cell 14 formed of Al_{y}Ga_{1-y}As that are coupled to one another via an AlGaAs tunnel junction 16. The device 10 also includes a Si cell 18 that is coupled to the Al_{y}Ga_{1-y}As cell 14 via an ultra thin Ge buffer layer 20. Another ultra thin Ge buffer layer 22 is formed on the backside of the Si cell 18, and a Ge cell 24 is formed on the Ge buffer layer 22. Electrical conductors 26 and 28 are applied to the top and bottom of the device 10 for connecting to power output terminals 30 and 32 respectively.

The cells 12, 14, 18 and 24 are each designed to provide photovoltaic responses over different solar energy ranges, and the thickness and bandgap energy of each sub-cell determines the current that will be produced by the overall cell. Each cell, therefore, may be designed to have a thickness and bandgap energy such that the current produced by each cell is equal to the current produced by each of the other cells, providing that that current output of the device is maximized. The power provided by the device is proportional to to the sum of the open-circuit voltages of each cell multiplied by the current provided by the minimum current produced by any of the sub-cells. For this reason, it is desirable to provide a large number of cells (to increase voltage output) yet to provide that the current output of each cell is equal to the current output of each of the other cells.

The general structure above provides that a larger number of AlₓGa₁₋ₓAs tandem sub-cells may be provided since the AlₓGa₁₋ₓAs layers are lattice matched independent of x, which determines the material's bandgap energy. The device also employs silicon (Si) as an active tandem sub-cell as well as a mechanical substrate and epitaxial substrate. Further, the device employs ultra thin Ge buffer layers that as used for lattice mismatch accommodation between AlₓGa₁₋ₓAs and Si, as well Ge and Si. The thin Ge buffer layers may be grown using ultra high vacuum chemical vapor deposition (UHV-CVD) growth followed by thermal cyclic annealing as disclosed in U.S. Pat. No. 6,635,110, the disclosure of which is hereby incorporated by reference. The Ge cell provides a bottom tandem cell for collecting photons that would otherwise be wasted. The epi-growth may be achieved, for example, via high-throughput chemical vapor deposition reactors capable of many-wafer-growth in a single batch, or hot wire chemical vapor deposition.

Analytical results have demonstrated that efficiency of the tandem device with four AlGaAs cells, a Si substrate cell, and a Ge backside sub-cell could be as high as 47% under one sun, and as high as 52.5% using a concentrator (e.g., 100 suns). The efficiencies should also increase with a tandem device having up to five AlGaAs cells. At this number of cells, the fixed bandgap energy difference between GaAs and Si does not allow for current matching with added AlGaAs cells. These high efficiencies are achieved, in part, due to the use of Ge buffer layers for lattice-matching between the AlGaAs and Si cells, and between the Ge and Si cells, as well as due to the AlGaAs growth on the Ge buffer and the use of the tunnel junctions between the AlGaAs cells.

As shown in FIG. 2, the process of making the device 10 begins (step 200) by growing an ultra thin Ge buffer layer on both sides (20 and 22) of the Si cell 18 (step 202). The Ge cell 24 is then grown on the bottom side of the Si cell 18 (step 204), and the device then undergoes post-growth annealing (step 206). The Al_{y}Ga_{1-y}As cell 14 is then grown on the Ge buffer layer 20 (step 208), followed again by post-growth annealing (step 210). The AlGaAs tunnel junction layer 16 is then grown on the Al_{y}Ga_{1-y}As cell 14 (step 212), and the second AlₓGa₁₋ₓAs cell 12 is grown on the tunnel junction layer 16.

AlGaAs is a well studied lattice matched system to Ge for all compositions, allowing for a range of choices of the band gaps of the top two cells and thus current matching. The (AlGaAs)^{m}/(Ge)/Si/(Ge)/Ge tandem cell structure proposed herein with m=1-5 provides absorption of light of wavelength shorter than the Ge direct band gap (−1600 nm) in the spectrum AM 1.5 G. This enhances the efficiency to higher than 50% with m=4 and further for m=5. This performance corresponds to collection of more than 75% photons in the AM 1.5 G spectrum below 4000 nm. This seamless increase of m is an advantage of using the AlGaAs system. Furthermore, the materials system proposed here includes the use of Si and Ge, which allows for the use of multiple SiGe layers on the backside of Si (as discussed below with reference to FIG. 5), allowing for up to an 8 layer, current-matched tandem cell to be made using this basic system.

The Si lattice constant is smaller than that of the other materials considered here, such as AlGaAs and Ge. As mentioned above, the Si plays the role of a solar cell as well as that of a mechanical and epitaxial substrate, so thick SiGe buffer growth technology is not necessary. The presence of a thick SiGe buffer layer between the AlGaAs and Si cells would absorb too many photons, robbing the bottom Si and Ge sub-cells of current and not allowing for efficient current matching. The Ge buffer growth technology mentioned above is desirable because it can produce a buffer layer thinner than approximately 60 nm. In any event, the effect of the buffer layers on photon absorption is not negligible. In general, the thicker the Ge buffer, the fewer photons will be transmitted to the lower-positioned Si and Ge layers. For thicker Ge buffers, the Al content of the AlGaAs layers, and accordingly the bandgap energy, must be made higher than the ideal calculated to reduce current generated in this layer as the Ge buffer thickness increases, to allow current matching with the lower Si and Ge cells which will lose some current due to the thicker Ge buffer. This is a built-in aspect of this invention that requires it to entail a range of layer thicknesses and AlₓGa₁₋ₓAs compositions within its definition.

Tunneling junctions must be placed between the AlGaAs tandem cells as discussed above. The doping profile should be sharp, requiring low temperature growth. The development of dual hetero-structure AlGaAs tunnel junctions is provided by the use of low temperature Ge buffer layers and post-growth cyclical annealing to substantially reduce dislocation density below 10⁷ cm⁻² in the Ge epilayers.

As shown in FIG. 3, a graph 40 of the total cumulative photocurrent available from absorption of all light in the solar spectrum in mA/cm² versus wavelength shows that if the thickness and bandgap energy of each cell is chosen appropriately, the current output of each cell may be equal to that of the other cells (e.g., 13 mA/cm² as shown). FIG. 3 shows that the AlₓGa₁₋ₓAs cell 12 provides a photovoltaic response to solar energy with wavelength shorter than about 600 nm, the Al_{y}Ga_{1-y}As cell 14 provides a photovoltaic response to solar energy in the wavelength range of about 600-800 nm, the Si cell 18 provides a photovoltaic response to solar energy in the wavelength range of about 800-1100 nm, and the Ge cell 24 provides a photovoltaic response to solar energy in the wavelength range of about 1100-1600 nm.

The post-growth annealing can alter the dopant profiles in the cells that are fabricated before it occurs. The most sensitive doping profile is at the AlGaAs tunnel junction between the AlGaAs/AlGaAs tandem sub-cells. Accordingly, in the multiple AlGaAs layer tandem cells described here, only the first AlGaAs layer that is deposited before the AlGaAs tunnel junction can be post-growth annealed. Since the first high-quality AlGaAs layer serves as a growth template for further AlGaAs layers, this does not represent a problem here.

FIG. 4 shows an illustrative diagrammatic band energy diagram for the device 10 of FIG. 1. The AlₓGa₁₋ₓAs cell 12 cell has a band structure as shown at 50, the Al_{y}Ga_{1-y}As cell 14 cell has a band structure as shown at 52, the Si cell 18 cell has a band structure as shown at 58, and the Ge cell has a band structure as shown at 62. The band structure of the coupling layers is also shown in FIG. 4, and the band structure of the AlGaAs tunnel junction layer 16 is shown at 52, while the band structure of the Ge buffer layers 20 and 22 is are shown at 56 and 60 respectively.

It is desirable to grow low dislocation density Ge and AlGaAs on ultra thin Ge buffers for certain embodiments of the invention. Also, ultra thin Ge buffers of high enough quality must be grown to allow for the growth of high quality Ge and AlGaAs cells thereon. It is important that the Ge buffer be as thin as possible, and preferably that it be thinner than 50 nm. A 60 nm Ge buffer layer has proven to be sufficient to produce high quality thick Ge-on-Si films.

A photovoltaic device 100 in accordance with another embodiment of the invention is shown in FIG. 5. The device 100 includes a Si cell 102 with two ultra thin Ge buffer layers (104 and 106) on either side of the Si cell 102. Onto the first Ge buffer layer 104 is grown a plurality of AlGaAs cells separated by AlGaAs tunnel junction layers. In particular, an Al_{z}Ga_{1-z}As cell 108 is shown grown on the Ge buffer layer 104, followed by an AlGaAs tunnel junction layer 110, followed by an Al_{y}Ga_{1-z}As cell 112. The process of growing AlGaAs layers and AlGaAs tunnel junction layers continues with increasing Al contents in the AlGaAs cell layers, until the final AlGaAs tunnel junction layer 114 and the final top AlₓGa₁₋ₓAs cell 116 is grown.

Similarly, onto the second Ge buffer layer 106 is grown a plurality of SiGe cells separated by SiGe tunnel junction layers. In particular, a SiᵤGe₁₋ᵤ cell 118 is shown grown on the Ge buffer layer 106, followed by a SiGe tunnel junction layer 120, followed by a SiᵥGe₁₋ᵥ cell 122. The process of growing SiGe layers and SiGe tunnel junction layers continues with increasing Ge contents in the SiGe cell layers, until the final SiGe tunnel junction layer 124 and Si_{w}Ge_{1-w} cell 126 is grown. Note that this final composition may include a pure Ge layer. Conductors 130 and 132 are applied to the top and bottom of the device for providing power output at terminals 134 and 136.

Examples of tandem cells in accordance with various embodiments may provide a variety of combinations of the above materials, including the following. A tandem cell may include (from top to bottom), an AlGaAs cell, a Ge buffer layer, a Si cell, another Ge buffer layer, and a Ge cell. Another tandem cell may include two or three AlGaAs cells separated by an AlGaAs tunnel junction layer followed by a Ge buffer layer, a Si cell, another Ge buffer layer, and a SiGe cell where the Si content may be zero. Another tandem cell may include four or five AlGaAs cells separated by AlGaAs tunnel junction layers, followed by a Ge buffer layer, a Si cell, another Ge buffer layer, and one, two or three SiGe cells, wherein the Si content of the bottom layer may be zero. Another tandem cell may include an AlGaAs cell followed by a Ge buffer layer, and a Si cell. Another tandem cell may include two, three or four AlGaAs cells separate by tunnel junction layers followed by a Ge buffer layer, and a Si cell.

Those skilled in the art will appreciate that numerous modifications and variations may be made to the above disclosed embodiments without departing from the spirit and scope of the invention.

1. A system for providing electrical power responsive to solar energy, said system comprising:
a Si cell for providing electrical power responsive to solar energy within a first frequency range;
a AlGaAs cell coupled to a first side of said Si cell, said AlGaAs cell providing electrical power responsive to solar energy within a second frequency range;
a Ge cell coupled to a second side of said Si cell said Ge cell providing electrical power responsive to solar energy within a third frequency range.

2. The system as claimed in claim 1, wherein said system further includes a thin Ge buffer layer on at least one side of the Si cell.

3. The system as claimed in claim 1, wherein said system further includes a thin Ge buffer layer on both sides of the Si cell.

4. The system as claimed in claim 1, wherein said system further includes a plurality of AlGaAs cells coupled to the first side of said Si cell.

5. The system as claimed in claim 1, wherein said system further includes two AlGaAs cells coupled to the first side of said Si cell.

6. The system as claimed in claim 1, wherein said system further includes three AlGaAs cells coupled to the first side of said Si cell.

7. A system for providing electrical power responsive to solar energy, said system comprising:
an Si cell for providing electrical power responsive to solar energy within a first frequency range;
a first AlGaAs cell coupled to a first side of said Si cell, said first AlGaAs cell providing electrical power responsive to solar energy within a second frequency range;
a second AlGaAs cell coupled to said first AlGaAs cell, said second AlGaAs cell providing electrical power responsive to solar energy within a third frequency range;
a Ge cell coupled to a second side of said Si cell said Ge cell providing electrical power responsive to solar energy within a fourth frequency range.

8. The system as claimed in claim 7, wherein said system further includes a thin Ge buffer layer on at least one side of the Si cell.

9. The system as claimed in claim 7, wherein said system further includes a thin Ge buffer layer on both sides of the Si cell.

10. The system as claimed in claim 7, wherein said system further includes an AlGaAs tunnel junction layer between said first AlaAs cell and said second AlGaAs cell.

11. The system as claimed in claim 7, wherein said Si cell, said first AlGaAs cell, said second AlGaAs cell and said Ge cell provide approximately the same current output during use.

12. A system for providing electrical power responsive to solar energy, said system comprising:
a Si cell for providing electrical power responsive to solar energy within a first frequency range;
a AlGaAs cell coupled to a first side of said Si cell, said AlGaAs cell providing electrical power responsive to solar energy within a second frequency range; and
a Ge buffer layer of less than about 60 nm between said Si cell and said AlGaAs cell.

13. The system as claimed in claim 12, wherein said system further includes a Ge cell coupled to a second side of said Si cell said Ge cell providing electrical power responsive to solar energy within a third frequency range.

14. The system as claimed in claim 12, wherein said system further includes a plurality of AlGaAs cells coupled to the first side of said Si cell.

15. The system as claimed in claim 12, wherein said system further includes two AlGaAs cells coupled to the first side of said Si cell.

16. The system as claimed in claim 12, wherein said system further includes three AlGaAs cells coupled to the first side of said Si cell.

17. The system as claimed in claim 12, wherein said system further includes four AlGaAs cells coupled to the first side of said Si cell.

18. The system as claimed in claim 12, wherein said system further includes five AlGaAs cells coupled to the first side of said Si cell, wherein an AlGaAs cell includes an aluminum (Al) content of substantially zero.

19. The system as claimed in claim 14, wherein said system further includes at least one AlGaAs tunnel junction layer between two AlGaAs cells.

20. A system for providing electrical power responsive to solar energy, said system comprising:
a Si cell for providing electrical power responsive to solar energy within a first frequency range;
a first AlGaAs cell coupled to a first side of said Si cell, said first AlGaAs cell providing electrical power responsive to solar energy within a second frequency range;
a second AlGaAs cell coupled to said first AlGaAs cell, said second AlGaAs cell providing electrical power responsive to solar energy within a third frequency range;
a first SiGe cell coupled to a second side of said Si cell, said first SiGe cell providing electrical power responsive to solar energy within a fourth frequency range.

21. The system as claimed in claim 20, wherein said system further includes a second SiGe cell coupled to said first SiGe cell, said second SiGe cell providing electrical power responsive to solar energy within a fifth frequency range.

22. The system as claimed in claim 21, wherein said system further includes an AlGaAs tunnel junction layer between said first AlGaAs cell and said second AlGaAs cell.

23. The system as claimed in claim 21, wherein said system further includes a SiGe tunnel junction layer between said first SiGe cell and said second SiGe cell.

24. The system as claimed in claim 21, wherein a SiGe cell includes a silicon (Si) content of substantially zero.

25. The system as claimed in claim 20, wherein said system further includes a thin Ge buffer layer on at least one side of the Si cell.

26. The system as claimed in claim 20, wherein said system further includes a thin Ge buffer layer on both sides of the Si cell.

27. The system as claimed in claim 20, wherein said Si cell, said first AlGaAs cell, said second AlGaAs cell, and said first SiGe cell provide approximately the same current output during use.

28. The system as claimed in claim 20, wherein said system further includes three AlGaAs cells coupled to the first side of said Si cell.

29. The system as claimed in claim 20, wherein said system further includes four AlGaAs cells coupled to the first side of said Si cell.

30. The system as claimed in claim 20, wherein said system further includes five AlGaAs cells coupled to the first side of said Si cell, wherein the first AlGaAs cell includes an aluminum (Al) content of substantially zero.
